(19) United States
(12) Patent Application Publication
(10) Pub. No.: US 2017/0370965 A1
(43) Pub. Date: Dec. 28, 2017

(54) ELECTRICAL PROBE AND JIG FOR THE SAME

(71) Applicant: CHROMA ATE INC., Taoyuan (TW)

(72) Inventors: Hsu-Chang HSU, Taoyuan (TW); Chiang-Cheng FAN, Taoyuan (TW); Li-Hsun CHEN, Taoyuan (TW); Chuan-Tse LIN, Taoyuan (TW); Ming-Hui WANG, Taoyuan (TW); Chung-Lin LIU, Taoyuan (TW); Ming-Ju CHUANG, Taoyuan (TW)

(73) Assignee: CHROMA ATE INC., Taoyuan (TW)

(21) Appl. No.: 15/608,663

(22) Filed: May 30, 2017

(30) Foreign Application Priority Data
Jun. 22, 2016 (TW) 105119640

(51) Int. Cl. G01R 1/067; G01N 27/04

(52) U.S. Cl. CPC G01R 1/06788; G01R 1/06777; G01R 1/06705; G01N 27/041

(57) ABSTRACT

An electrical probe includes a base body and a probe head. The base body has a main body portion and at least one positioning portion, and the positioning portion protrudes from the main body portion. The probe head is detachably disposed on the main body portion of the base body. The probe head has an outer edge away from a side of a central axis of the main body portion, and the positioning portion protrudes from the outer edge.

### CROSS-REFERENCE TO RELATED APPLICATIONS

This non-provisional application claims priority under 35 U.S.C. §119(a) on Patent Application No(s). 105119640 filed in Taiwan, R.O.C. on Jun. 22, 2016, the entire contents of which are hereby incorporated by reference.

### TECHNICAL FIELD

The disclosure relates to an electrical probe and a jig, more particularly to an electrical probe for measuring resistance values or voltage values, and a jig for replacing a probe head of the electrical probe.

### BACKGROUND

A probe is utilized for measuring resistance values or voltage values at the present industry, especially a probe for high current flow from tens of Ampere to hundreds of Ampere. Before shipping products, the manufacturers will use the probe to conduct electric properties tests to confirm the yield rate and the reliability of the products. In order to meet the requirements of less heat generation and large contacting area, the probe will directly contact the surface of the product to accurately measure the resistance value or voltage value under the electric properties tests.

In general, a probe head will be damaged in the process of electric properties tests because of high current flow, so that the probe head is needed to be replaced regularly. A conventional probe includes a detachable probe head mounted on a main body, so that the users is able to conveniently and fast replace the probe head. However, when the probe head is replaced, because of lacking an appropriate fixation on both the probe head and the probe body, the main body is easy to move together with the probe head, so that the relative displacement between the probe head and the probe body is overly small, and thus the probe head is difficult to be loosen from the main body. Some manufacturers use a tool (such as a wrench) to hold the main body, and use other tools (such as other wrenches) to replace the probe head. However, the steps of replacement will be more complicated and its operation will be more difficult, so that it could not contribute to improve the replacement efficiency of the probe head.

### SUMMARY

The present disclosure discloses an electrical probe and a jig, in order to solve the problems of complicated steps and difficult operation when the probe head is replaced.

According to the disclosure, an electrical probe includes a base body and a probe head. The base body includes a main body portion and at least one positioning portion, and the positioning portion protrudes from the main body portion. The probe head is detachably disposed on the main body portion of the base body. The probe head has an outer edge located on a side of the probe head away from a central axis of the main body portion, and the positioning portion protrudes from the outer edge.

According to another disclosure, a jig adaptive for replacing the aforementioned probe head includes a positioning member and a movable member. The positioning member has an accommodation space and an opening which are connected to each other, and the positioning member is sleeved on the positioning portion of the electrical probe by the opening when the probe head is replaced. The movable member is movably disposed in the accommodation space, and the movable member is adaptive for replacing the probe head. The movable member has a recess, and the probe head is able to locate in the recess. When the probe head is replaced, the movable member is sleeved on the probe head along an axial direction of the positioning member, and the movable member is pressed against the positioning portion.

### BRIEF DESCRIPTION OF THE DRAWINGS

The present disclosure will become better understood from the detailed description given hereinbelow and the accompanying drawings which are given by way of illustration only and thus are not limitative to the present disclosure and wherein:

FIG. 1A is a perspective view of an electrical probe according to a first embodiment;

FIG. 1B is an exploded view of the electrical probe in FIG. 1A;

FIG. 1C is a bottom view of the electrical probe in FIG. 1A;

FIG. 1D is an exploded view of a jig according to the first embodiment;

FIG. 1E is a cross-sectional view of the jig in FIG. 1D which is fixed to the electrical probe in FIG. 1A;

FIG. 2A is an exploded view of the electrical probe according to a second embodiment;

FIG. 2B is a bottom view of the electrical probe in FIG. 2A;

FIG. 3 is a bottom view of the electrical probe according to a third embodiment;

FIG. 4 is a bottom view of the electrical probe according to a fourth embodiment;

FIG. 5 is a cross-sectional view of the electrical probe according to a fifth embodiment.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

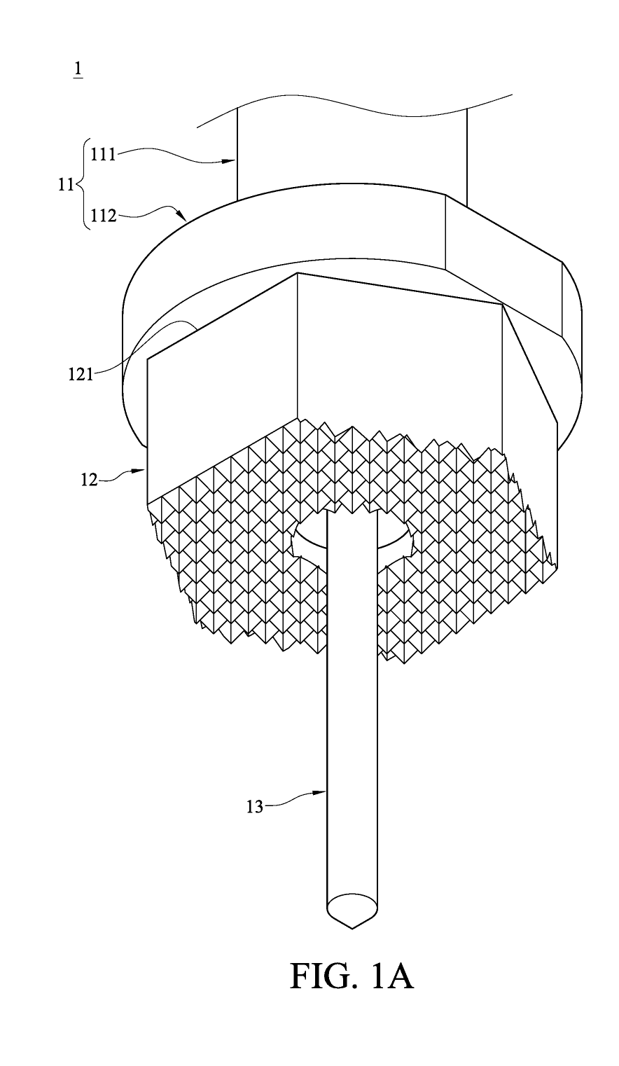

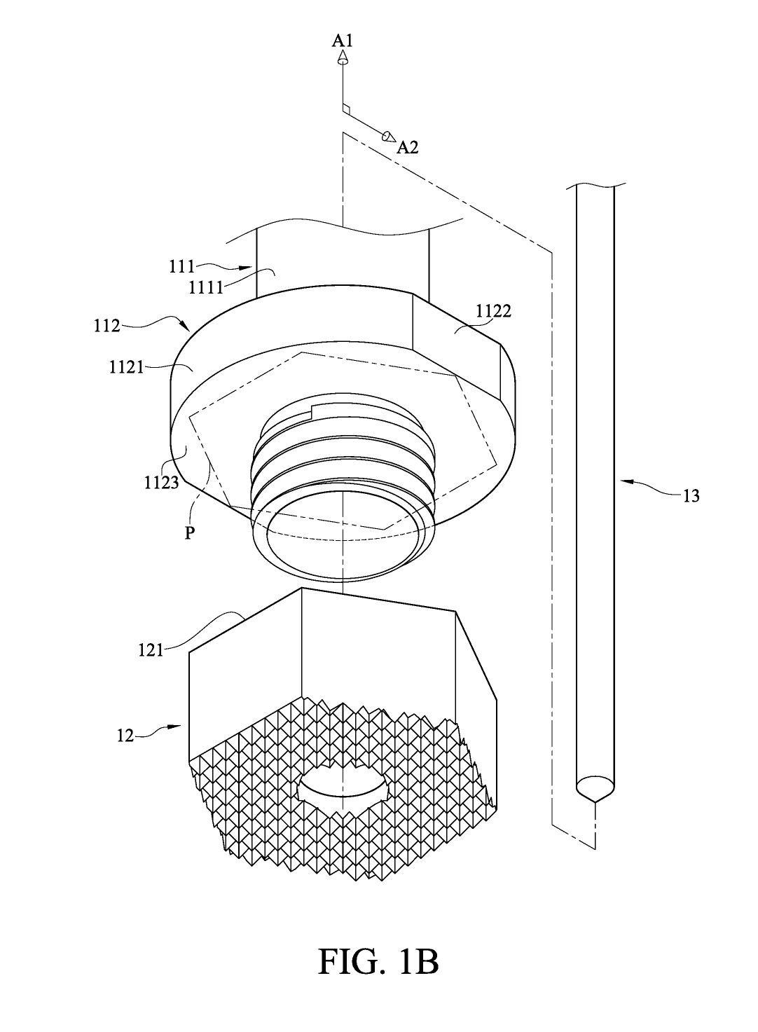

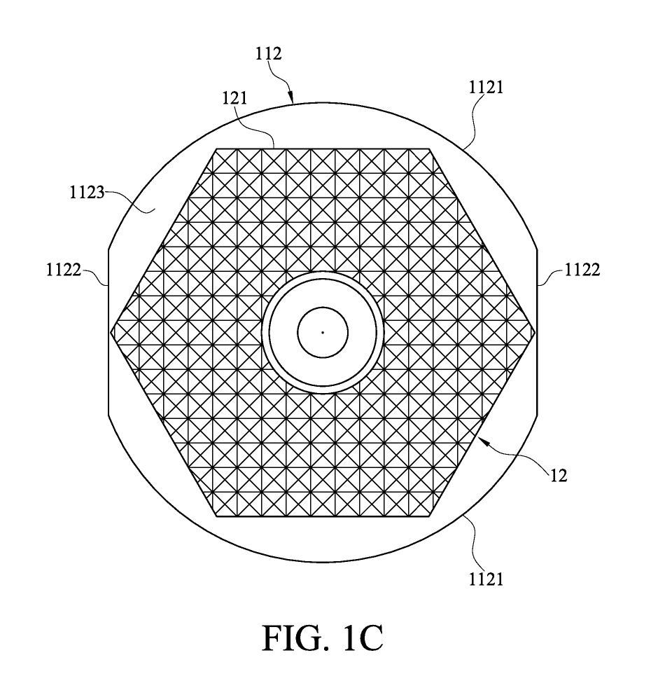

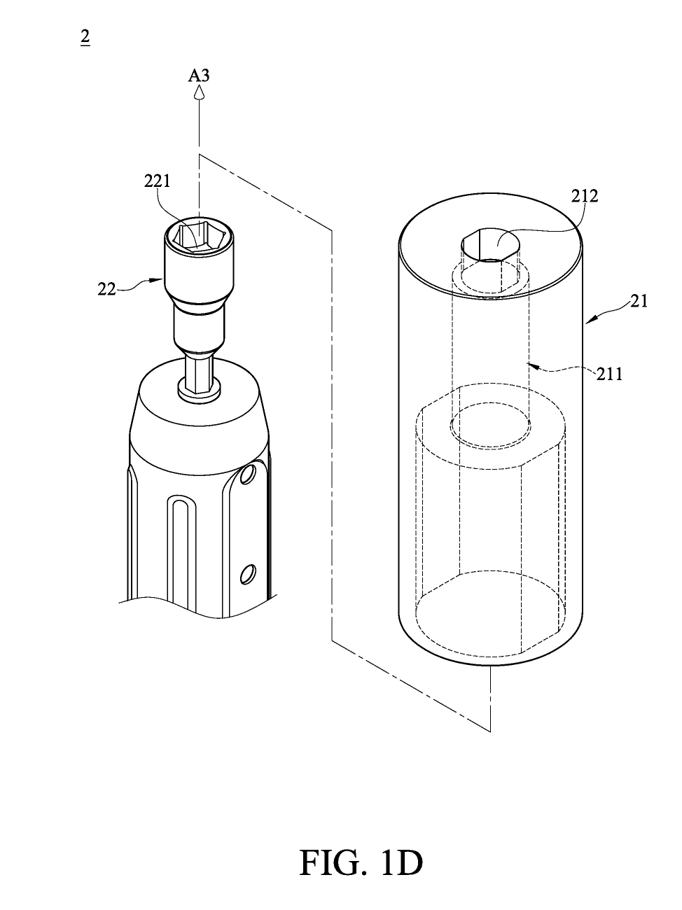

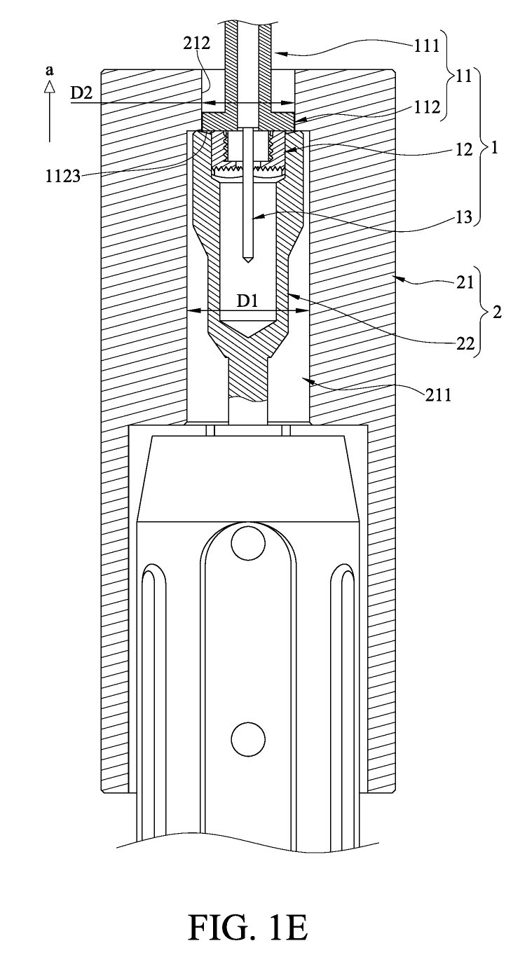

Please refer to FIG. 1A to FIG. 1C. FIG. 1A is a perspective view of an electrical probe according to a first embodiment. FIG. 1B is an exploded view of the electrical probe in FIG. 1A. FIG. 1C is a bottom view of the electrical probe in FIG. 1A.

In this embodiment, an electrical probe 1 includes a base body 11, a probe head 12 and a pin 13. The base body 11, the probe head 12 and the pin 13, for example, are all made of conductive materials. The electrical probe 1 is utilized to press against a test object (not shown in the drawings) so as to measure the resistance of the test object. In detail, the electric current flows from the probe head 12 into the test object, and then the electric current flows from the test object into the pin 13 for resistance measurement.

The base body 11 includes a main body portion 111 and a positioning portion 112 which are connected to each other, and the positioning portion 112 protrudes from the main body portion 111. In detail, the main body portion 111 has a lateral surface 1111 located on a side of the main body portion 111 away from a central axis A1 of the main body portion 111. The positioning portion 112 surrounds the lateral surface 1111, and the positioning portion 112 extends along a radial direction A2 of the main body portion 111. The edge of the positioning portion 112 has two circular sections 1121 and two linear sections 1122 which are connected to each other. The two circular sections 1121 are opposite to each other, and the two linear sections 1122 are located between the two circular sections 1121. As shown in FIG. 1C, each circular section 1121 is convex in this embodiment. The edge of the positioning portion 112 is formed by the circular sections 1121 and the linear sections 1122, and its shape is dependent on the circular sections 1121 and the linear sections 1122. The positioning portion 112 further has a stopper surface 1123 which is surrounded by the two circular sections 1121 and the two linear sections 1122. The shape and the extension direction of the positioning portion 112 are not limited thereto. In other embodiments, the shape of the positioning portion 112 is rectangular or circular, and there is an acute angle between the extension direction of the positioning portion 112 and the radial direction A2 of the main body portion 111. Moreover, the main body portion 111 is integral with the positioning portion 112 in this embodiment, but the disclosure is not limited thereto. In other embodiments, the main body portion 111 and the positioning portion 112 are two separated members, and the positioning portion 112 is locked to or screwed to the main body portion 111.

The probe head 12 is detachably disposed on the main body portion 111 of the base body 11. The probe head 12 has an outer edge 121 located on a side of the probe head 12 away from the central axis A1 of the main body portion 111, and the positioning portion 112 protrudes from the outer edge 121. In this embodiment, the probe head 12 is screwed to the main body portion 111, and the shape of the probe head 12 is a regular hexagon, but the disclosure is not limited thereto. In other embodiments, the probe head 12 is fastened to or locked to the main body portion 111, and the shape of the probe head 12 is rectangular or circular. There is a projection P of the probe head 12 onto the stopper surface 1123, and the projection P is surrounded by the two circular sections 1121 and the two linear sections 1122. In detail, in this embodiment, the area of the stopper surface 1123 is larger than the area of the projection P of the probe head 12, so that the two circular sections 1121 and the two linear sections 1122 are farther from the central axis A1 of the main body portion 111 than the outer edge 121 of the probe head 12. The pin 13 penetrates through the main body portion 111 of the base body 11 and the probe head 12.

Please refer to FIG. 1D and FIG. 1E. FIG. 1D is an exploded view of the jig according to the first embodiment. FIG. 1E is a cross-sectional view of the jig in FIG. 1D which is fixed to the electrical probe in FIG. 1A. The first embodiment further discloses a jig 2 which is adaptive for replacing the probe head 12 of the electrical probe 1. The jig 2 includes a positioning member 21 and a movable member 22. The positioning member 21 is adaptive to be fixed to the positioning portion 112 of the base body 11. In detail, in this embodiment, the positioning member 21 has an accommodation space 211 and an opening 212 which are connected to each other. The cross section size D2 of the opening 212 matches the positioning portion 112, so that the positioning member 21 is able to be sleeved on the positioning portion 112 by the opening 212, and the positioning portion 112 of the electrical probe 1 is held by the positioning member 21, but the disclosure is not limited thereto. In other embodiments, the positioning member 21 can be fixed to the positioning portion 112 by means of blocks fastened with slots. In this embodiment, the cross section size D1 of the accommodation space 211 in the radial direction of the positioning member 21 is larger than the cross section size D2 of the opening 212, but the disclosure is not limited thereto. In other embodiments, the cross section size D1 of the accommodation space 211 is equal to the cross section size D2 of the opening 212.

The movable member 22 is movably disposed in the accommodation space 211, and the movable member 22 is adaptive for replacing the probe head 12. In detail, the movable member 22 has a recess 221, and the probe head is adaptive to be located in the recess 221. the size of the recess 221 matches the cross section size of the probe head 12 in the radial direction thereof. The movable member 22 is able to be driven by a power source (such as motors or users, not shown in the drawings) so as to rotate relative to the positioning member 21 around its central axis A3. In this embodiment, the movable member 22 is fixed to the probe head 12 by fitting the probe head 12 into the recess 221, but the disclosure is not limited thereto. In other embodiments, the movable member 22 is fixed to the probe head 12 by blocks fastened with slots.

The following illustrates how to use the jig 2 to replace the probe head 12. As shown in FIG. 1E, firstly, the positioning member 21 of the jig 2 is sleeved on the positioning portion 112 of the electrical probe 1. Then, the movable member 22 is moved along an axial direction (the arrow a shown in FIG. 1E) of the positioning member 21 in the accommodation space 211 to press against the stopper surface 1123 of the positioning portion 112, and the probe head 12 is fitted into the recess 221 when the movable member 22 is pressed against the stopper surface 1123 of the positioning portion 112. Finally, the movable member 22 is rotated so as to loosen the probe head 12, and thus the probe head 12 is detached from the probe head 12. After the aforementioned detachment is finished, a new probe head is mounted on the base body 11.

According to the disclosure, when the probe head 12 is replaced, the positioning member 21 of the jig 2 is fixed to the positioning portion 112 of the base body 11 protruding from the outer edge 121 of the probe head 12, so that an interference between the positioning member 21 and the positioning portion 112 is favorable for firmly holding the positioning member 21 at a determined position. The movable member 22 of the jig 2 is able to rotate the probe head 12 relative to the base body 11. In the process of replacement, since the base body 11 is fixed to the positioning member 21 of the jig 2, the base body 11 is prevented from moving together with the probe head 12, thereby improving replacement efficiency. Therefore, the user is able to easily and effectively replace the probe head 12 by the jig 2. In addition, when the movable member 22 is sleeved on the probe head 12, the positioning portion 112 is provided as guidance about the position of the movable member 22 in the accommodation space 211. For example, when the movable member 22 is pressed against the positioning portion 112, the user knows that the movable member 22 is located at a position where the probe head 12 is completely fitted into the recess 221. Therefore, it is favorable for confirming whether the movable member 22 is completely sleeved on the probe head 12 or not.

In this embodiment, the probe head 12 and the main body portion 111 are screwed to each other, so that the jig 2 is able to detach the probe head 12 by rotating the movable member 22, but the disclosure is not limited thereto. In other embodiments, when the probe head 12 is tightly fitted to the main body portion 111, the movable member 22 of the jig 2 is able to detach the probe head 12 by pullout means. In addition, when replacing the probe head 12, the user is able to detach the old probe head 12 and mount a new probe head 12 by the jig 2. In this embodiment, the probe head 12 is replaced by the jig 2, but the disclosure is not limited to the jig 2. In other embodiments, the user uses a wrench or other conventional tools to replace the probe head 12.

In this embodiment, as shown in FIG. 1A, the positioning portion 112 of the base body 11 of the electrical probe 1 surrounds around the lateral surface 1111 of the main body portion 111. Therefore, it is favorable for providing sufficient area on the positioning portion 112 for contacting the positioning member 21 of the jig 2, so as to maintain stable connection between the jig 2 and the base body 11, when the jig 2 is fixed to the electrical probe 1.

In addition, as shown in FIG. 1E, the cross section size D1 of the accommodation space 211 is larger than the cross section size D2 of the opening 212. Therefore, there is a sufficient space for the rotation of the movable member 22 so as to prevent unfavorable interference between the positioning member 21 and the movable member 22 in the process of replacement. In other embodiments, when the cross section size D1 of the accommodation space 211 equals the cross section size D2 of the opening 212, in order to prevent unfavorable interference, the electrical probe 1 is designed to make the projection P of the probe head 12 onto the stopper surface 1123 surrounded by the side edge of the positioning portion 112 (as shown in FIG. 1B). In other words, the interference between the positioning member 21 and the movable member 22 is prevented as long as the edge of the positioning portion 112 surrounds the projection P of the probe head 12 onto the stopper surface 1123.

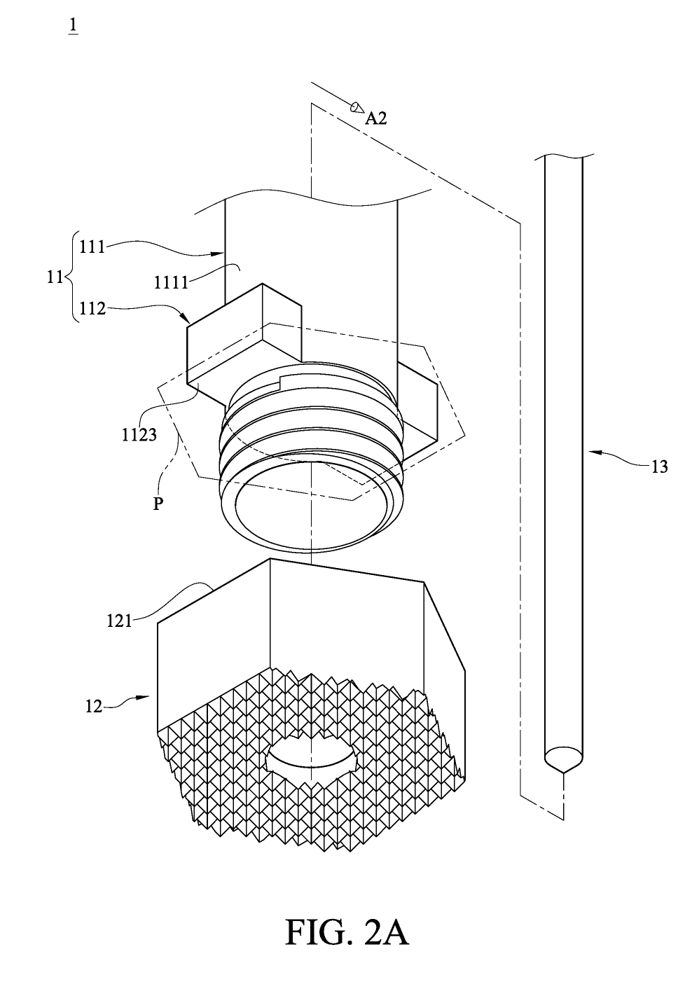

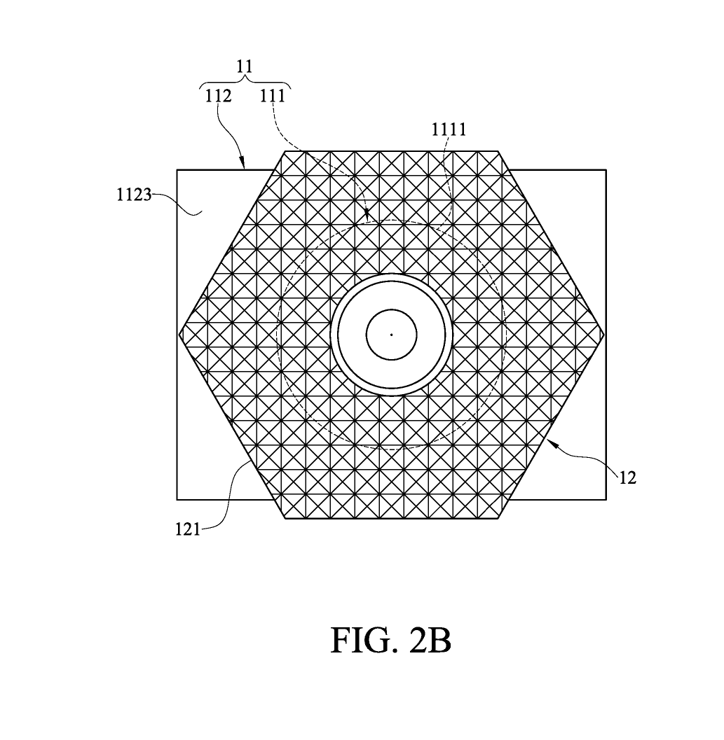

In the first embodiment, the number of the positioning portion is one, but the disclosure not limited thereto. Please refer to FIG. 2A and FIG. 2B. FIG. 2A is an exploded view of the electrical probe according to a second embodiment. FIG. 2B is a bottom view of the electrical probe in FIG. 2A. Since the second embodiment and the first the embodiment are similar, the following only illustrates the difference between the first and the second embodiments.

In this embodiment, the base body 11 of the electrical probe 1 includes two positioning portions 112. The two positioning portions 112 are located at an end of the main body portion 111 close to the probe head 12, the two positioning portions 112 extends in opposite direction to be away from each other, and the two positioning portions 112 protrude from the outer edge 121 of the probe head 12. In detail, the two positioning portions 112 are located on the lateral surface 1111 of the main body portion 111, and extend along the direction A2 of the main body portion 111 to respectively protrude from the left side and the right side of the outer edge 121, from the view of FIG. 2A. In addition, at least a part of the projection P of the probe head 12 onto the stopper surface 1123 protrudes from the edge of the stopper surface 1123; that is, the two sections of the positioning portion 112 are covered with the probe head 12. In this embodiment, when the probe head 12 of the electrical probe 1 is replaced, if the cross section of the accommodation space in a radial direction of the positioning member is larger than the opening, it is favorable for preventing avoid the interference between the positioning member and the movable member.

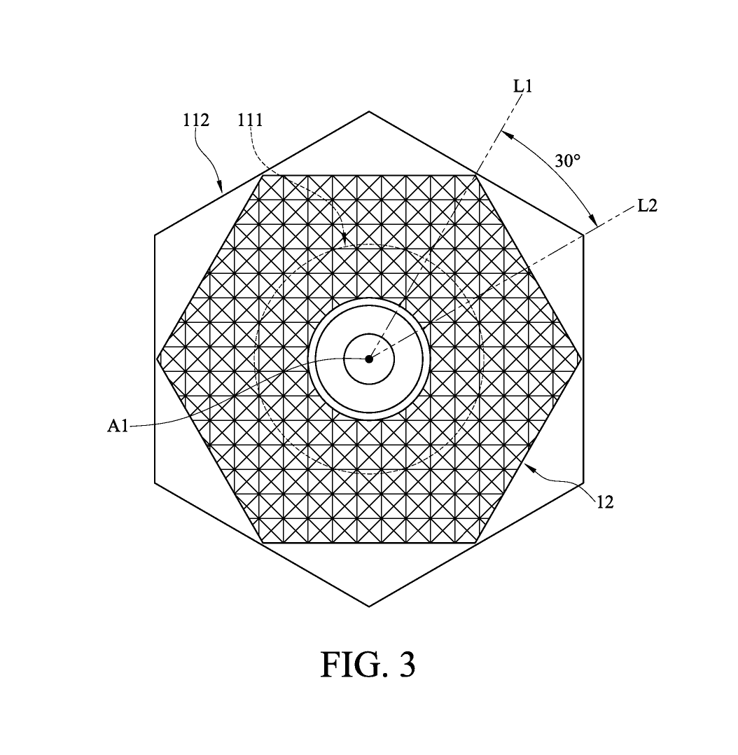

Please refer to FIG. 3 which is a bottom view of the electrical probe according to a third embodiment. Since the third embodiment and the first the embodiment are similar, so the following only illustrates the difference between the third and the first embodiment. In this embodiment, the shapes of the positioning portion 112 and the probe head 12 each are a regular hexagon. There is an extension line L1 passing through the central axis A1 of the main body portion 111 and one vertex of the probe head 12, and there is an extension line L2 passing through the central axis A1 and another vertex of positioning portion 112. An angle located between the extension lines L1 and L2 is 30 degrees.

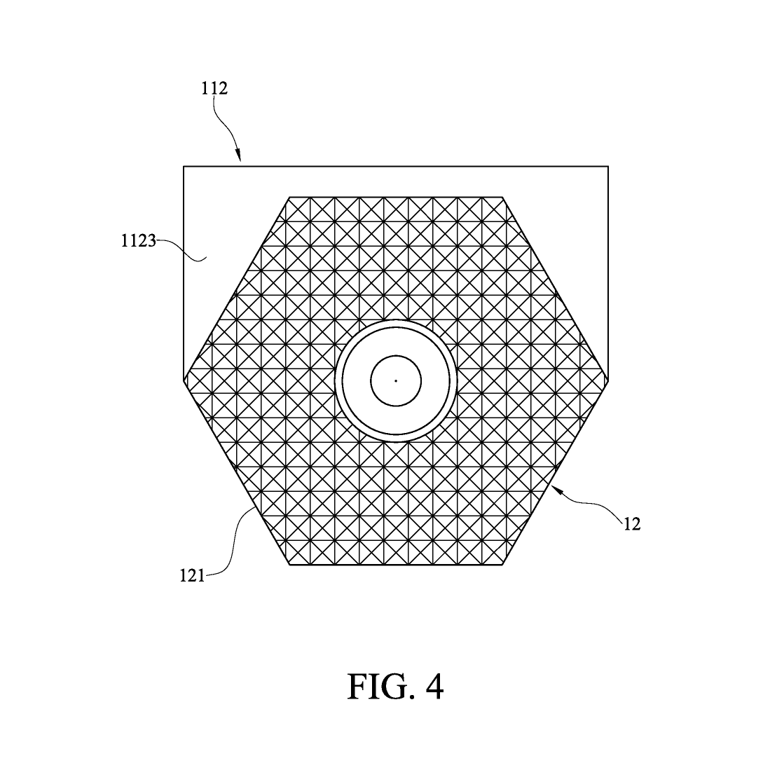

Please refer to FIG. 4 which is a bottom view of the electrical probe according to a fourth embodiment. Since the fourth embodiment and the first the embodiment are similar, so the following only illustrates the difference between the fourth and the first embodiment. In this embodiment, a part of the edge of the positioning portion 112 overlaps with the outer edge 121 of the probe head 12, and the other part of the edge of positioning portion 112 is farther from the central axis of the probe head 12 than the outer edge 121.

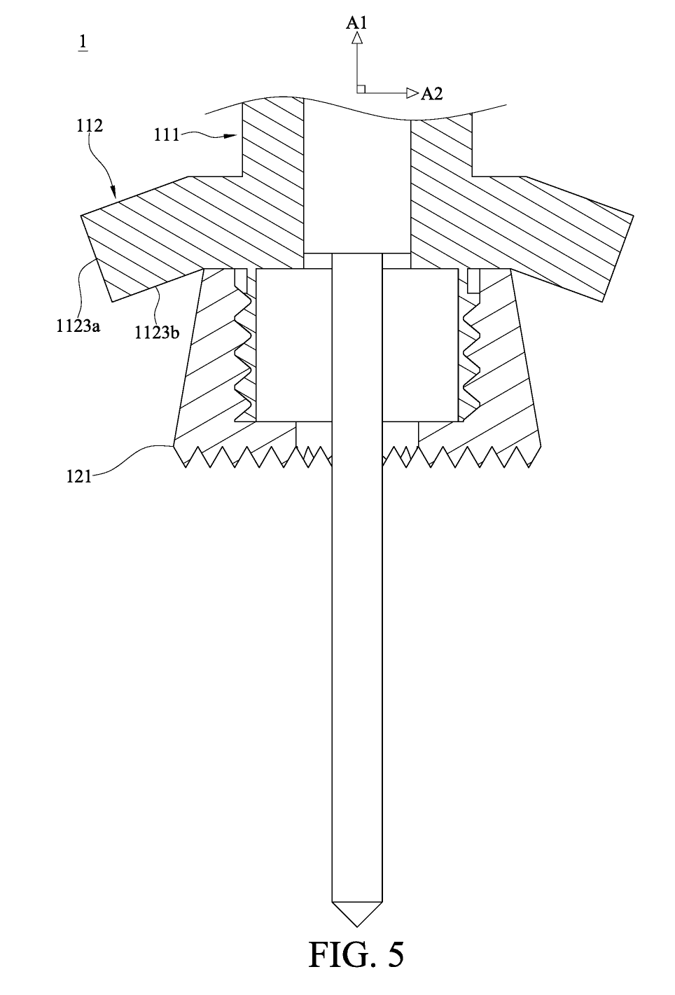

Please refer to FIG. 5 which is a cross-sectional view of the electrical probe according to a fifth embodiment. Since the fifth embodiment and the first the embodiment are similar, so the following only illustrates the difference between the fifth and the first embodiment. In this embodiment, the positioning portion 112 extends along an extension direction, and an acute angle is between this extension direction and the radial direction A2 of the main body portion 111. The stopper surface of the positioning portion 112 has a circular inclined section 1123a and a flat section 1123b, and the probe head 12 is cone-shaped. The outer edge 121 of the probe head 12 is located on the bottom surface of the cone-shaped probe head 12. That is, the probe head 12 has a plurality of edges, and one of the edges farthest from the central axis A1 of the main body portion 111 are regarded as the outer edge 121 of the probe head 12.

According to the disclosure, the positioning portion of the base body of the electrical probe protrudes from the outer edge of the probe head, so that interference between the positioning member of the jig and the positioning portion is favorable for firmly holding the positioning member at a determined position. When the probe head is replaced, since the base body is fixed to the positioning member of the jig, the base body is prevented from moving together with the probe head, thereby improving replacement efficiency. Therefore, the user is able to easily and effectively replace the probe head by the jig.

In addition, when the movable member is sleeved on the probe head, the positioning portion is provided as guidance about the position of the movable member in the accommodation space. Therefore, it is favorable for confirming whether the movable member is completely sleeved on the probe head or not.

What is claimed is:

1. An electrical probe, comprising:
a base body comprising a main body portion and at least one positioning portion, and the at least one positioning portion protruding from the main body portion; and
a probe head detachably disposed on the main body portion of the base body, the probe head having an outer edge located on a side of the probe head away from a central axis of the main body portion, and the at least one positioning portion protruding from the outer edge.

2. The electrical probe according to claim 1, wherein the main body portion has a lateral surface located on a side of the main body portion away from the central axis of the main body portion, and the at least one positioning portion surrounds the lateral surface.

3. The electrical probe according to claim 1, wherein the at least one positioning portion extends along a radial direction of the main body portion.

4. The electrical probe according to claim 1, wherein a number of the at least one positioning portion is two, the two positioning portions are located at an end of the main body portion, the two positioning portions extends in opposite direction to be away from each other, and the two positioning portions protrude from the outer edge of the probe head.

5. The electrical probe according to claim 1, wherein the at least one positioning portion has a stopper surface facing the probe head, and a projection of the probe head onto the stopper surface is surrounded by the stopper surface.

6. The electrical probe according to claim 5, wherein the stopper surface has two circular sections and two linear sections which are connected to each other, the two circular sections are opposite to each other, and the two linear sections are located between the two circular sections.

7. The electrical probe according to claim 1, wherein the at least one positioning portion has a stopper surface facing the probe head, and at least a part of a projection of the probe head onto the stopper surface protrudes from at least one edge of the stopper surface.

8. A jig, being adaptive for replacing the probe head of the electrical probe according to claim 1, comprising:
a positioning member having an accommodation space, and the positioning member being fixable to the at least one positioning portion; and
a movable member which is movably disposed in the accommodation space, the movable member being adaptive for replacing the probe head;
wherein when the probe head is replaced by the jig, the movable member is fixed to the probe head along an axial direction of the positioning member, and the movable member is pressed against the at least one positioning portion.

9. The jig according to claim 8, wherein the movable member is rotatable around its central axis, and the movable member is rotatable relative to the at least one positioning portion so as to replace the probe head.

10. The jig according to claim 8, wherein the positioning member further has an opening connected to the accommodation space, the positioning member is sleeved on the at least one positioning portion by the opening when the probe head is replaced, a cross section of the accommodation space in a radial direction of the positioning member is larger than the opening, the movable member has a recess, and the probe head is located in the recess when the probe head is replaced.
